(19) United States
(12) Patent Application Publication
(10) Pub. No.: US 2006/0163581 A1
(43) Pub. Date: Jul. 27, 2006

(54) Fabrication of strained silicon film via implantation at elevated substrate temperatures

(75) Inventor: Agajan Suvkhanov, Portland, OR (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/042,275

(22) Filed: Jan. 24, 2005

(51) Int. Cl. H01L 29/12; H01L 21/20; H01L 21/425

(52) U.S. Cl. 257/65; 257/616; 438/508; 438/514

(57) ABSTRACT

A strained-silicon film is disclosed. A silicon-germanium film is made by ion implantation of germanium into an epitaxial silicon layer, preferably at a temperature in the range of 200 C to 400 C. The wafer is annealed in situ or optionally after implantation. A silicon film is applied to the silicon-germanium film in a conventional manner to create the strained-silicon substrate.

### BACKGROUND

The present invention generally relates to the fabrication of silicon films. The invention specifically relates to the fabrication of high-quality strained-silicon films for metal oxide semiconductors.

There is a need for higher speed in transistors, as devices become more intricate and require more complex computations. Chip manufacturers have conventionally improved chip performance by shrinking transistors. The ability to shrink transistors further is diminishing.

One solution has been to improve chip performance by using strained silicon. Building a strain into silicon decreases the resistance to carrier flow through the crystal lattice, thereby allowing carriers to pass more easily through the silicon lattice. With less resistance, carriers flow at higher drive current. With higher drive current, transistors switch faster between on-off states, meaning the chip can operate at a higher frequency and therefore compute more quickly. Tensile strain stretches the interatomic distances in the silicon crystal, increasing the mobility of carriers, and making N-type transistors run faster. Compressive strain, in which the interatomic distances are reduced, has the opposite effect and makes P-type transistors run faster.

One way to create a strained-silicon film for an N-type transistor is to deposit an alloy of silicon and germanium onto an existing silicon wafer. This alloy layer has properties much like silicon. The germanium, however, causes the silicon atoms to be spaced farther apart than they would be in pure silicon. If a thin film of silicon is then applied to the silicon-germanium alloy layer, the silicon atoms of the thin film, as they settle onto the alloy layer, follow the expanded pattern of the alloy layer. Accordingly, the bonds between the silicon atoms of the thin film are stretched and the interatomic distances are increased, increasing the mobility of electrons and allowing for a faster transistor, as explained above.

This technique of manufacturing a strained-silicon substrate on top of a silicon-germanium alloy has been accomplished by using an epitaxial film growth reactor. A silicon layer is grown first. Germanium is then added to grow a graded film layer of silicon-germanium. Once a needed concentration of germanium has been obtained, such as 20 percent, a layer of silicon is grown epitaxially on top of the graded film of silicon-germanium. This technique requires a high-temperature anneal for defectivity control, to bring the films to crystalline quality.

This technique, however, is plagued by high defect rates, high costs for operating and maintaining an epitaxial film growth reactor, high complications in operating and maintaining an epitaxial film growth reactor, and the time, labor, and equipment costs of having an additional anneal step.

Accordingly, a need exists for a cost-effective and simpler method to create a high-quality silicon-germanium film, in order to manufacture a high-quality strained-silicon film.

### OBJECTS AND SUMMARY

An object of an embodiment of the present invention is to provide a system to manufacture high-quality strained-silicon films at lower cost and with fewer complications.

A further object of an embodiment of the present invention is to provide a system to manufacture high-quality strained-silicon films with minimal defects.

A further object of an embodiment of the present invention is to provide a system to manufacture high-quality strained-silicon films without costly modifications to existing equipment.

A further object of an embodiment of the present invention is to manufacture high-quality strained silicon films in fewer manufacturing steps.

A further object of an embodiment of the present invention is to provide a system to manufacture high-quality silicon-germanium films for fabrication of strained-silicon films at lower cost and with fewer complications.

A further object of an embodiment of the present invention is to provide a system to manufacture high-quality silicon-germanium films for fabrication of strained-silicon films with minimal defects.

A further object of an embodiment of the present invention is to provide a system to manufacture high-quality silicon-germanium films for fabrication of strained-silicon films without costly modifications to existing equipment.

A further object of an embodiment of the present invention is to manufacture high-quality silicon-germanium films for fabrication of strained-silicon films in fewer manufacturing steps.

Briefly, an embodiment of the present invention provides a method of using germanium implantation into an epitaxial silicon substrate at elevated temperatures to create a silicon-germanium layer. In the preferred embodiment, germanium ion implantation is accomplished at 200 C to 400 C, improving damage recovery during the implantation process by providing an in situ anneal. The implantation process in one embodiment includes annealing after implantation. A thin layer of epitaxial silicon is applied to the silicon-germanium film to create a strained-silicon film.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 is a flow chart of the preferred embodiment of the method of the present invention; and

FIG. 2 is a cross-sectional diagram of the product of the present invention.

### DESCRIPTION

While the invention may be susceptible to embodiment in different forms, there are shown in the drawings, and herein will be described in detail, specific embodiments of the invention. The present disclosure is to be considered an example of the principles of the invention, and is not intended to limit the invention to that which is illustrated and described herein.

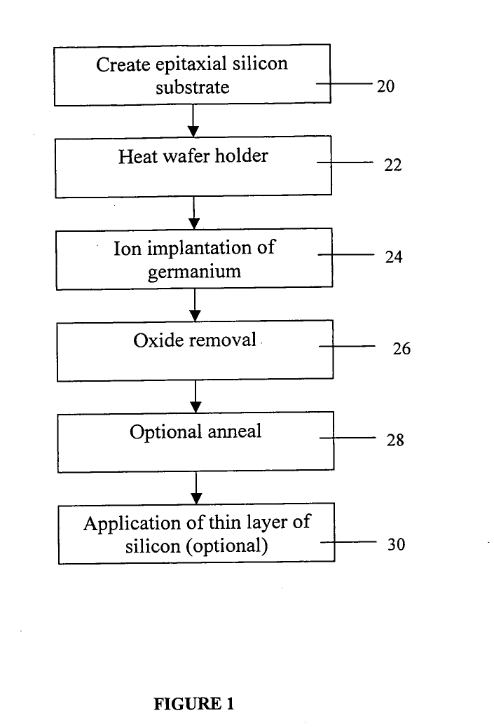

A flow chart of the method of manufacture of the strained-silicon film is shown in FIG. 1. An epitaxial silicon substrate is first created in a wafer holder in a conventional manner (step 20). The process of the preferred embodiment of the present invention uses the same wafer holders as used in the prior art method. Accordingly, increased capital costs are minimized by use of the present invention, as new wafer holders are not needed.

The wafer holder is then heated to implantation temperature (step 22). Germanium ions are implanted into the epitaxial silicon substrate by ion implantation (step 24). Implantation of the germanium ions thus creates a silicon-germanium film in the epitaxial silicon substrate.

Germanium ions are implanted preferably at a temperature in the range of 200 C to 400 C. The use of this higher temperature range effectively provides an in situ anneal and eliminates the need for an additional annealing step. In situ annealing will promote incorporation of germanium into the silicon film. Additionally, in situ annealing significantly improves damage recovery during the implantation process. Accordingly, implantation at this temperature range will lead to low crystalline defect rates, a critical consideration in the manufacture of strained-silicon substrates.

Following implantation, oxide removal is accomplished in a conventional manner (step 26).

In another embodiment, annealing of the wafers is accomplished after ion implantation (step 28), depending on the ion dose of the germanium ion beam.

In one embodiment, the product can be now be used to create a transistor. Because the top layer is a silicon-germanium film, the interatomic distances between silicon atoms are increased, created the strained conditions discussed above.

In the preferred embodiment, the wafer with a silicon-germanium film can now be used for creation of a strained-silicon film in the usual manner. Epitaxial application of silicon to the wafer of the present invention creates a thin layer of silicon that conforms to the pattern of the silicon-germanium film (step 30). The silicon of the thin layer accordingly forges stretched bonds, due to the increased space between silicon atoms in the wafer. Those stretched bonds in the silicon film provide for increased electron mobility due to decreased resistance. The increased mobility allows for faster switching in transistors made from the wafer of the present invention, thereby leading to increased performance.

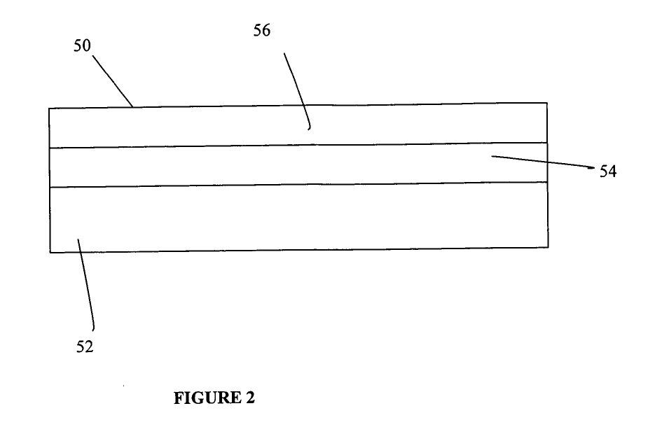

The product of the present invention is illustrated in FIG. 2, which shows a strained-silicon substrate 50 in cross section (not to scale). An epitaxial silicon substrate 52 has a silicon-germanium film 54 created by ion implantation. A thin layer of strained silicon 56 has been applied to the silicon-germanium film 54.

While embodiments of the present invention are shown and described, it is envisioned that those skilled in the art may devise various modifications of the present invention without departing from the spirit and scope of the appended claims.

What is claimed is:

1. A strained-silicon film, comprising:
an epitaxial silicon layer;
a silicon-germanium film made by germanium ion implantation into said epitaxial silicon layer; and
a silicon film applied to said silicon-germanium film.

2. The film of claim 1, wherein said implantation is made at a temperature between about 200 C and 400 C.

3. The film of claim 1, further comprising the step of post-implantation annealing.

4. The film of claim 3, wherein said implantation is made at a temperature between about 200 C and 400 C.

5. A silicon-germanium film, comprising:
an epitaxial silicon layer; and
a silicon-germanium film made by germanium ion implantation into said epitaxial silicon layer.

6. The film of claim 5, wherein said implantation is made at a temperature between about 200 C and 400 C.

7. The film of claim 5, further comprising the step of post-implantation annealing.

8. The film of claim 7, wherein said implantation is made at a temperature between about 200 C and 400 C.

9. A method of making a strained-silicon film, comprising:
creating a silicon-germanium film in an epitaxial silicon layer by ion implantation of germanium into said epitaxial silicon layer; and
applying a silicon film to said silicon-germanium film.

10. The method of claim 9, wherein said implantation step occurs at a temperature between about 200 C and 400 C.

11. The method of claim 9, further comprising the step of post-implantation annealing.

12. The method of claim 11, wherein said implantation step occurs at a temperature between about 200 C and 400 C.

13. A method of making a silicon-germanium film, comprising:
creating a silicon-germanium film in an epitaxial silicon layer by ion implantation of germanium into said epitaxial silicon layer.

14. The method of claim 13, wherein said implantation step occurs at a temperature between about 200 C and 400 C.

15. The method of claim 13, further comprising the step of post-implantation annealing.

16. The method of claim 15, wherein said implantation step occurs at a temperature between about 200 C and 400 C.
